(19) United States
(12) Patent Application Publication
(10) Pub. No.: US 2026/0254568 A1
(43) Pub. Date: Aug. 27, 2026

(54) METHOD, SYSTEM, AND APPARATUS FOR RETRANSMISSION IN WIRELESS COMMUNICATIONS

(71) Applicant: Huawei Technologies Co., Ltd., Shenzhen (CN)

(72) Inventors: Van Hung Vu, Ottawa (CA); Huazi Zhang, Zhejiang (CN); Yu Cao, Kanata (CA)

(21) Appl. No.: 19/465,689

(22) Filed: Jan. 30, 2026

Related U.S. Application Data
(63) Continuation of application No. PCT/CN2024/074836, filed on Jan. 31, 2024.
(60) Provisional application No. 63/530,796, filed on Aug. 4, 2023.

(51) Int. Cl. H04L 1/1812; H03M 13/11; H04L 1/00

(52) U.S. Cl. CPC H04L 1/1819; H03M 13/1102; H04L 1/0057; H04L 1/0071

(57) ABSTRACT

Embodiments of the present application include communication methods and communication apparatuses. A method includes: transmitting a retransmission including one or more cross-CB coded blocks, where the cross-CB coded blocks includes a first cross-CB coded block, and the first cross-CB coded block is generated by encoding, according to an LDPC code, a part of information bits of the CBs, where a code rate of the retransmission is lower than a code rate of the initial transmission. Thus, a receiving apparatus can decode a cross-CB coded block in a current retransmission. If the cross-CB coded blocks are decoded successfully, the part of the information bits can be considered as frozen bits, which allows the rest of information bits in the previous (re)transmission to be decoded with a lower CR.

### CROSS-REFERENCE TO RELATED APPLICATIONS

This application is a continuation of International Patent Application No. PCT/CN2024/074836, filed on Jan. 31, 2024, which claims to the benefit of U.S. Patent Application No. 63/530,796, filed on Aug. 4, 2023, applications of which are incorporated herein by reference in their entirety.

### TECHNICAL FIELD

Embodiments of the present application relate to the field of communications, and more specifically, to a communication method and a communication apparatus. For example, the communication method and the communication apparatus may be used for a downlink transmission, or a sidelink transmission, or an uplink transmission.

### BACKGROUND

In wireless communication, data can be transmitted between communication apparatus, and the data can be represented by a transport block (TB) in a physical layer. Further, the TB can be segmented and encoded by a forward error correction (FEC) code to generate multiple code blocks (CBs) for a transmission. A retransmission is required if the data transmitted in an initial transmission was not decoded successfully. How to efficiently perform retransmission is a problem to be solved.

### SUMMARY

Embodiments of the present application provide a communication method and a communication apparatus. The technical solutions may improve retransmission performance.

According to a first aspect, an embodiment of the present application provides a communication method, and the method could be performed by a transmitting apparatus. The transmitting apparatus may be a communication device (for example, a user equipment (UE), or a base station), or be a component (e.g., a chip, a circuit, or a processing system) configured in the communication device. The method includes: transmitting an initial transmission including multiple code blocks (CBs); transmitting a retransmission including one or more cross-CB coded blocks, where the cross-CB coded blocks include a first cross-CB coded block, and the first cross-CB coded block is generated by encoding, according to a low density parity check (LDPC) code, a part of information bits of the CBs, wherein a code rate of the retransmission is lower than a code rate of the initial transmission.

The first cross-CB coded block can include one or more cross-CB coded blocks. For example, the first cross-CB coded block can be referred to as the first cross-CB coded block set or the first set of cross-CB coded blocks.

According to the above technical solution, a cross-CB coded block in a current retransmission can be generated by encoding, according to an LDPC code, a part of information bits of a previous (re) transmission. A receiving apparatus can decode a cross-CB coded block in the current retransmission. If the cross-CB coded blocks are decoded successfully, the part of the information bits can be considered as frozen bits (i.e., be known at decoders), which allows the rest of information bits in the previous (re) transmission can be decoded with a lower code rate. Compared to traditional HARQ IR that requires decoding a long codeword, the above technical solution can offer lower decoding complexity by decoding multiple short codewords, and improve retransmission performance.

In a possible design, the part of information bits of the CBs includes one or more of: bits corresponding to variable nodes of each CB, where degrees of the variable nodes are less than a threshold; bits corresponding to ending-most positions of each CB; or bits corresponding to beginning-most positions of each CB.

According to the above technical solution, some specific information bits can be retransmitted by the cross-CB coded block. For example, information bits corresponding to variable nodes with higher degrees are more likely decoded successfully since they receive more information from adjacent check nodes. So, information bits corresponding to variable nodes with lower degrees can be retransmitted.

In a possible design, where the retransmission includes a first retransmission including the first cross-CB coded block and a second retransmission including a second cross-CB coded block, and the second cross-CB coded block is generated by encoding, according to an LDPC code, part of information bits of the first cross-CB coded block.

According to the above technical solution, for multiple retransmissions, a cross-CB coded block in current retransmission can be generated by encoding, according to an LDPC code, a part of information bits of previous retransmission, and a receiving apparatus can decode a cross-CB coded block in current retransmission.

In a possible design, where the first cross-CB coded block includes multiple cross-CB coded blocks, the part of information bits of the first cross-CB coded block includes one or more of: bits corresponding to variable nodes of each cross-CB coded block, where degrees of the variable nodes are less than a threshold; bits corresponding to ending-most positions of each cross-CB coded block; or bits corresponding to beginning-most positions of each cross-CB coded block.

In a possible design, where the transmitting the retransmission including the one or more cross-CB coded blocks includes: transmitting the first retransmission including the first cross-CB coded block; performing a reordering operation in information bits of the first cross-CB coded block; or performing a reordering operation in information bits of the first cross-CB coded block, and performing an interleaving operation in the part of information bits of the first cross-CB coded block; generating the second cross-CB coded block by encoding, according to an LDPC code, the part of information bits of the first cross-CB coded block; and transmitting the second retransmission including the second cross-CB coded block.

In a possible design, where the retransmission includes i^{th} retransmission and j^{th} retransmission, i>j, and a code rate of the i^{th} retransmission satisfies the following form:

$$\frac{{K}_{j} - {K}_{i}}{{N}_{j} - {K}_{i}} < \frac{{K}_{i}}{{N}_{i}}$$

where:

$$\frac{{K}_{i}}{{N}_{i}}$$

represents the code rate of the i^{th} retransmission; Kᵢ represents the number of information bits in each CB of the i^{th} retransmission; Nᵢ represents code bits of the i^{th} retransmission; Kⱼ represents the number of information bits in each CB of the j^{th} retransmission; and Nⱼ represents code bits of the j^{th} retransmission.

In a possible design, where the method further includes: performing interleaved operation in the part of information bits of the CBs; generating the first cross-CB coded block by encoding, according to an LDPC code, part of information bits of the CBs.

In a possible design, where the method further includes: receiving a negative acknowledgement; and the transmitting the retransmission including the one or more cross-CB coded blocks includes: in response to the negative acknowledgement, transmitting the retransmission including the cross-CB coded block.

According to the above technical solution, a retransmission can be transmitted if CBs are not successfully decoded in the initial transmission. Specifically, if the CBs transmitted in the initial transmission are not decoded successfully, the receiving apparatus can transmit the negative acknowledgement which indicates the CBs transmitted in the initial transmission are not decoded successfully, and in response to the negative acknowledgement, the retransmission can be transmitted.

In a possible design, where the method further includes: transmitting an indication indicating the code rate of the retransmission and/or the code rate of the initial transmission.

According to a second aspect, an embodiment of the present application provides a communication method, and the method could be performed by a receiving apparatus. The receiving apparatus may be a communication device (for example, a UE, or a base station), or be a component (e.g., a chip, a circuit, or a processing system) configured in the communication device. The method includes: receiving an initial transmission including multiple code blocks (CBs); receiving a retransmission including one or more cross-CB coded blocks, wherein the cross-CB coded blocks includes a first cross-CB coded block, and the first cross-CB coded block is generated by encoding, according to a low density parity check (LDPC) code, part of information bits of the CBs, wherein a code rate of the retransmission is lower than a code rate of the initial transmission.

In a possible design, wherein the method further includes: decoding the cross-CB coded block of the retransmission, and then decoding the CBs of the initial transmission based on decoded results of the cross-CB coded block.

In a possible design, wherein the part of information bits of the CBs includes one or more of: bits corresponding to variable nodes of each CB, wherein degrees of the variable nodes are less than a threshold; bits corresponding to ending-most positions of each CB; or bits corresponding to beginning-most positions of each CB. For example, the bits corresponding to variable nodes of each CB are referred to bits corresponding to variable nodes with smallest degrees.

In a possible design, wherein the retransmission includes a first retransmission including the first cross-CB coded block and a second retransmission including a second cross-CB coded block, and the second cross-CB coded block is generated by encoding, according to an LDPC code, part of information bits of the first cross-CB coded block.

In a possible design, wherein the first cross-CB coded block includes multiple cross-CB coded blocks, the part of the information bits of the first cross-CB coded block includes one or more of: bits corresponding to variable nodes of each cross-CB coded block, wherein degrees of the variable nodes are less than a threshold; bits corresponding to ending-most positions of each cross-CB coded block; or bits corresponding to beginning-most positions of each cross-CB coded block.

In a possible design, wherein the retransmission includes i^{th} retransmission and j^{th} retransmission, i>j, and a code rate of the i^{th} retransmission satisfies the following form:

$$\frac{{K}_{j} - {K}_{i}}{{N}_{j} - {K}_{i}} < \frac{{K}_{i}}{{N}_{i}}$$

where:

$$\frac{{K}_{i}}{{N}_{i}}$$

represents the code rate of the i^{th} retransmission; Kᵢ represents the number of information bits in each CB of the i^{th} retransmission; Nᵢ represents code bits of the i^{th} retransmission; Kᵢ represents the number of information bits in each CB of the j^{th} retransmission; and Nⱼ represents code bits of the j^{th} retransmission.

In a possible design, wherein before the receiving a retransmission, the method further includes: transmitting a negative acknowledgement in case of failure to decode the CBs.

In a possible design, the method further includes: receiving an indication indicating the code rate of the retransmission and/or the initial transmission.

Various implementations of the second aspect correspond to various implementations of the first aspect. For the various implementations and the beneficial technical effects of the various implementations of the second aspect, reference may be made to the descriptions of the relevant implementations of the first aspect, which will not be repeated here.

According to a third aspect, a communication apparatus is provided, and configured to perform the method in any possible implementation of the foregoing aspects. Specifically, the apparatus includes a unit configured to perform the method in any possible implementation of the foregoing aspects.

According to a fourth aspect, another communication apparatus is provided, including a processor. The processor is coupled to a memory, and may be configured to execute one or more instructions in the memory, to implement the method in any possible implementation of the various aspects. The memory may be an on-chip storage unit inside the processor, or may be an off-chip storage unit that is coupled to the memory and located outside the processor. In a possible implementation, the apparatus further includes the memory. In a possible implementation, the apparatus further includes a communication interface, and the processor is coupled to the communication interface.

In a possible design, the communication apparatus may be a UE, may be a chip, a circuit, or a processing system configured in the UE, or may be a device including the UE.

In a possible design, the communication apparatus may be a base station, may be a chip, a circuit, or a processing system configured in the base station, or may be a device including the base station.

According to a fifth aspect, a computer-readable storage medium is provided. The computer-readable storage medium stores a computer program, and when the computer program is executed by a communication apparatus, the communication apparatus is enabled to implement the method in any possible implementation of the foregoing aspects.

According to a sixth aspect, a computer program product including one or more instructions is provided. When the instructions are executed by a computer, a communication apparatus is enabled to implement the method in any possible implementation of the foregoing aspects.

According to a seventh aspect, a computer program is provided. When the computer program is executed by a computer, a communication apparatus is enabled to implement the method in any possible implementation of the foregoing aspects.

According to an eighth aspect, a communication system is provided. The communication system includes a first communication apparatus and/or a second communication apparatus, the first communication apparatus is configured to perform the method in any possible implementation of the first aspect, and the second communication apparatus is configured to perform the method in any possible implementation of the second aspect.

According to a ninth aspect, an apparatus for implementing the method in any possible implementation of the foregoing aspects is provided.

### DESCRIPTION OF DRAWINGS

FIG. 1 is a schematic diagram of an application scenario according to this application;

FIG. 2 illustrates an example communication system 100;

FIG. 3 illustrates another example of an ED 110 and a base station 170a, 170b and/or 170c;

FIG. 4 is an example of units or modules in a device;

FIG. 5 is an example of generating 4 VCBs from 4 CBs;

FIG. 6 is a schematic flowchart of a communication method 600 according to an embodiment of this application;

FIG. 7 is an example of a retransmission scheme of this application;

FIG. 8 is another example of a retransmission scheme of this application;

FIG. 9 is an example of a cross-CB IF coding scheme with two retransmissions of this application;

FIG. 10 is a schematic block diagram of a communication apparatus according to an embodiment of this application;

FIG. 11 is a schematic block diagram of another communication apparatus according to an embodiment of this application.

### DESCRIPTION OF EMBODIMENTS

The following describes technical solutions of the present application with reference to the accompanying drawings.

The technical solutions in embodiments of this application may be applied to various communication systems, such as a fifth generation (5G) wireless communication system, a new radio (NR) wireless communication system, a Long Term Evolution (LTE) system, an LTE frequency division duplex (FDD) system, an LTE time division duplex (TDD) system, a wireless local area network (WLAN), a satellite communication system, or other evolving communication systems, such as a sixth generation (6G) wireless communication system.

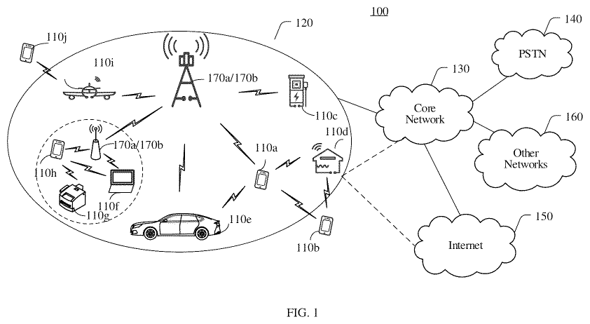

For ease of understanding of the embodiments of this application, a communication system shown in FIG. 1-FIG. 4 is used as an example to describe in detail a communication system to which the embodiments of this application are applicable.

Referring to FIG. 1, as an illustrative example without limitation, a simplified schematic illustration of a communication system is provided. The communication system 100 includes a radio access network 120. The radio access network 120 may be a next generation (e.g. 6G or later) radio access network, or a legacy (e.g. 5G, 4G, 3G or 2G) radio access network. One or more communication electronic devices (ED) 110a-110j (generically referred to as ED 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also, the communication system 100 includes a public switched telephone network (PSTN) 140, the Internet 150, and other networks 160.

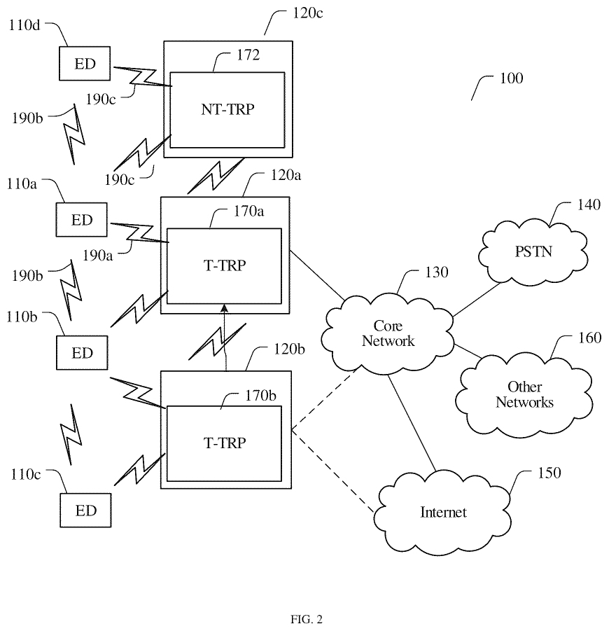

Referring to FIG. 2, an example communication system 100 is illustrated. In general, the communication system 100 enables multiple wireless or wired elements to communicate data and other content. The purpose of the communication system 100 may be to provide content, such as voice, data, video, and/or text, via broadcast, multicast and unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of the terrestrial communication system and the non-terrestrial communication system. For example, integrating a non-terrestrial communication system (or components thereof) into a terrestrial communication system can result in what may be considered a heterogeneous network including multiple layers. Compared to conventional communication networks, the heterogeneous network may achieve better overall performance through efficient multi-link joint operation, more flexible functionality sharing, and faster physical layer link switching between terrestrial networks and non-terrestrial networks.

The terrestrial communication system and the non-terrestrial communication system may be considered sub-systems of the communication system. In the example shown, the communication system 100 includes electronic devices (ED) 110a-110d (generically referred to as ED 110), radio access networks (RANs) 120a-120b, non-terrestrial communication network 120c, a core network 130, a public switched telephone network (PSTN) 140, the Internet 150, and other networks 160. The RANs 120a-120b include respective base stations (BSs) 170a-170b, which may be generically referred to as terrestrial transmit and receive points (T-TRPs) 170a-170b. The non-terrestrial communication network 120c includes an access node 120c, which may be generically referred to as a non-terrestrial transmit and receive point (NT-TRP) 172.

Any ED 110 may be alternatively or additionally configured to interface, access, or communicate with any other T-TRP 170a-170b and NT-TRP 172, the Internet 150, the core network 130, the PSTN 140, the other networks 160, or any combination of the preceding. In some examples, ED 110a may communicate an uplink and/or downlink transmission over an interface 190a with T-TRP 170a. In some examples, the EDs 110a, 110b and 110d may also communicate directly with one another via one or more sidelink air interfaces 190b. In some examples, ED 110d may communicate an uplink and/or downlink transmission over an interface 190c with NT-TRP 172.

The air interfaces 190a and 190b may use similar communication technology, such as any suitable radio access technology. For example, the communication system 100 may implement one or more channel access methods, such as code division multiple access (CDMA), time division multiple access (TDMA), frequency division multiple access (FDMA), orthogonal FDMA (OFDMA), or single-carrier FDMA (SC-FDMA) in the air interfaces 190a and 190b. The air interfaces 190a and 190b may utilize other higher dimension signal spaces, which may involve a combination of orthogonal and/or non-orthogonal dimensions.

The air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs and one or multiple NT-TRPs for multicast transmission.

The RANs 120a and 120b are in communication with the core network 130 to provide the EDs 110a 110b, and 110c with various services such as voice, data, and other services. The RANs 120a and 120b and/or the core network 130 may be in direct or indirect communication with one or more other RANs (not shown), which may or may not be directly served by core network 130, and may or may not employ the same radio access technology as RAN 120a, RAN 120b or both. The core network 130 may also serve as a gateway access between (i) the RANs 120a and 120b or EDs 110a 110b, and 110c or both, and (ii) other networks (such as the PSTN 140, the Internet 150, and the other networks 160). In addition, some or all of the EDs 110a 110b, and 110c may include functionality for communicating with different wireless networks over different wireless links using different wireless technologies and/or protocols. Instead of wireless communication (or in addition thereto), the EDs 110a 110b, and 110c may communicate via wired communication channels to a service provider or switch (not shown), and to the Internet 150. PSTN 140 may include circuit switched telephone networks for providing plain old telephone service (POTS). Internet 150 may include a network of computers and subnets (intranets) or both, and incorporate protocols, such as Internet Protocol (IP), Transmission Control Protocol (TCP), and User Datagram Protocol (UDP). EDs 110a 110b, and 110c may be multimode devices capable of operation according to multiple radio access technologies, and incorporate multiple transceivers necessary to support such.

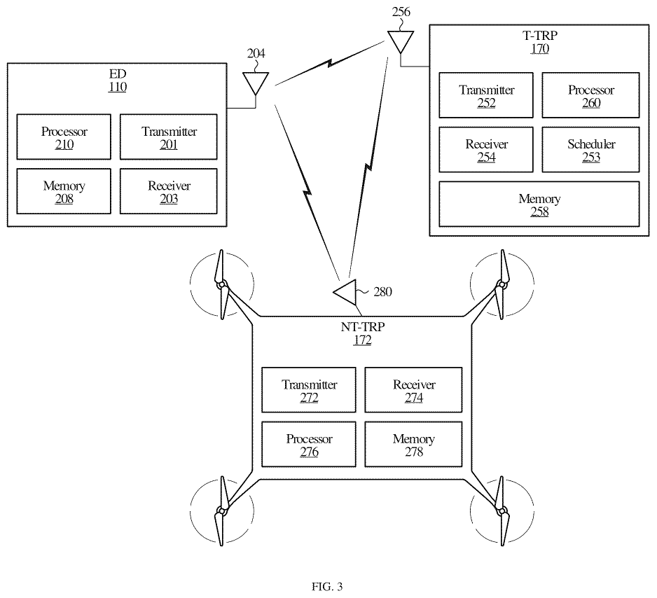

Referring to FIG. 3, an example of an ED 110 and a base station 170a, 170b and/or 170c is illustrated. The ED 110 is used to connect persons, objects, machines, etc. The ED 110 may be widely used in various scenarios, for example, cellular communications, device-to-device (D2D), vehicle to everything (V2X), peer-to-peer (P2P), machine-to-machine (M2M), machine-type communications (MTC), internet of things (IOT), virtual reality (VR), augmented reality (AR), industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, an industrial device, or an apparatus (e.g. a communication module, a modem, or a chip) in the foregoing devices, among other possibilities. Future generation EDs 110 may be referred to as other terms. The base station 170a and 170b is a T-TRP and will hereafter be referred to as T-TRP 170. Also, as shown in FIG. 3, an NT-TRP will hereafter be referred to as NT-TRP 172. Each ED 110 connected to T-TRP 170 and/or NT-TRP 172 can be dynamically or semi-statically turned on (i.e., established, activated, or enabled), turned off (i.e., released, deactivated, or disabled) and/or configured in response to one or more of: connection availability or connection necessity.

The ED 110 includes a transmitter 201 and a receiver 203 coupled to one or more antennas 204. Only one antenna 204 is illustrated. One, some, or all of the antennas may alternatively be panels. The transmitter 201 and the receiver 203 may be integrated, e.g. as a transceiver. The transceiver is configured to modulate data or other content for transmission by at least one antenna 204 or network interface controller (NIC). The transceiver is also configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 may store software instructions or modules configured to implement some or all of the functionality and/or embodiments described herein and that are executed by the processing unit(s) 210. Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache, and the like.

The ED 110 may further include one or more input/output devices (not shown) or interfaces (such as a wired interface to the Internet 150 in FIG. 1). The input/output devices permit interaction with a user or other devices in the network. Each input/output device includes any suitable structure for providing information to or receiving information from a user, such as a speaker, microphone, keypad, keyboard, display, or touch screen, including network interface communications.

The ED 110 further includes a processor 210 for performing operations including those related to preparing a transmission for uplink transmission to the NT-TRP 172 and/or T-TRP 170, those related to processing downlink transmissions received from the NT-TRP 172 and/or T-TRP 170, and those related to processing sidelink transmissions to and from another ED 110. Processing operations related to preparing a transmission for uplink transmission may include operations such as encoding, modulating, transmit beamforming, and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g. by detecting and/or decoding the signaling). An example of signaling may be reference signals transmitted by NT-TRP 172 and/or T-TRP 170. In some embodiments, the processor 276 implements the transmit beamforming and/or receive beamforming based on the indication of beam direction, e.g. beam angle information (BAI), received from T-TRP 170. In some embodiments, the processor 210 may perform operations related to network access (e.g. initial access) and/or downlink synchronization, such as operations related to detecting a synchronization sequence, decoding and obtaining the system information, etc. In some embodiments, the processor 210 may perform channel estimation, e.g. using reference signals received from the NT-TRP 172 and/or T-TRP 170.

Although not illustrated, the processor 210 may form part of the transmitter 201 and/or receiver 203. Although not illustrated, the memory 208 may form part of the processor 210.

The processor 210, and the processing components of the transmitter 201 and the receiver 203 may each be implemented by the same or different one or more processors that are configured to execute instructions stored in a memory (e.g. in memory 208). Alternatively, some or all of the processor 210, and the processing components of the transmitter 201 and the receiver 203 may be implemented using dedicated circuitry, such as a programmed field-programmable gate array (FPGA), a graphical processing unit (GPU), or an application-specific integrated circuit (ASIC).

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), or a wireless router, a relay station, a remote radio head, a terrestrial node, a terrestrial network device, or a terrestrial base station, base band unit (BBU), remote radio unit (RRU), radio unit (RU), active antenna unit (AAU), remote radio head (RRH), central unit (CU), distribute unit (DU), positioning node, among other possibilities. The T-TRP 170 may be macro BSs, pico BSs, relay node, donor node, or the like, or combinations thereof. The T-TRP 170 may refer to the foregoing devices or apparatus (e.g. a communication module, a modem, or a chip) in the foregoing devices.

The CU (or CU-control plane (CP) and CU-user plane (UP)), DU or RU may be known by other names in some implementations. For example, in an open RAN (ORAN) system, the CU may also be referred to as open CU (O-CU), DU may also be referred to as open DU (O-DU), CU-CP may also be referred to open CU-CP (O-CU-CP), CU-UP may also be referred to as open CU-UP (O-CU-CP), and RU may also be referred to open RU (O-RU). Any one of the CU (or CU-CP, CU-UP), DU, or RU may be implemented through a software module, a hardware module, or a combination of software and hardware modules.

In some embodiments, the parts of the T-TRP 170 may be distributed. For example, some of the modules of the T-TRP 170 may be located remotely from the equipment housing the antennas of the T-TRP 170, and may be coupled to the equipment housing the antennas over a communication link (not shown) sometimes known as front haul, such as a common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment housing the antennas of the T-TRP 170. The modules may also be coupled to other T-TRPs. In some embodiments, the T-TRP 170 may actually be a plurality of T-TRPs that are operating together to serve the ED 110, e.g. through coordinated multipoint transmissions.

The T-TRP 170 includes at least one transmitter 252 and at least one receiver 254 coupled to one or more antennas 256. Only one antenna 256 is illustrated. One, some, or all of the antennas may alternatively be panels. The transmitter 252 and the receiver 254 may be integrated as a transceiver. The T-TRP 170 further includes a processor 260 for performing operations including those related to: preparing a transmission for downlink transmission to the ED 110, processing an uplink transmission received from the ED 110, preparing a transmission for backhaul transmission to NT-TRP 172, and processing a transmission received over backhaul from the NT-TRP 172. Processing operations related to preparing a transmission for downlink or backhaul transmission may include operations such as encoding, modulating, precoding (e.g. MIMO precoding), transmit beamforming, and generating symbols for transmission. Processing operations related to processing received transmissions in the uplink or over backhaul may include operations such as receive beamforming, and demodulating and decoding received symbols. The processor 260 may also perform operations related to network access (e.g. initial access) and/or downlink synchronization, such as generating the content of synchronization signal blocks (SSBs), generating the system information, etc. In some embodiments, the processor 260 also generates the indication of beam direction, e.g. BAI, which may be scheduled for transmission by a scheduler 253. The processor 260 performs other network-side processing operations described herein, such as determining the location of the ED 110, determining where to deploy NT-TRP 172, etc. In some embodiments, the processor 260 may generate signaling, e.g. to configure one or more parameters of the ED 110 and/or one or more parameters of the NT-TRP 172. Any signaling generated by the processor 260 is sent by the transmitter 252. Note that “signaling”, as used herein, may alternatively be called control signaling. Dynamic signaling may be transmitted in a control channel, e.g. a physical downlink control channel (PDCCH), and static or semi-static higher layer signaling may be included in a packet transmitted in a data channel, e.g. in a physical downlink shared channel (PDSCH).

The scheduler 253 may be coupled to the processor 260. The scheduler 253 may be included within or operated separately from the T-TRP 170, which may schedule uplink, downlink, and/or backhaul transmissions, including issuing scheduling grants and/or configuring scheduling-free (“configured grant”) resources. The T-TRP 170 further includes a memory 258 for storing information and data. The memory 258 stores instructions and data used, generated, or collected by the T-TRP 170. For example, the memory 258 may store software instructions or modules configured to implement some or all of the functionality and/or embodiments described herein and executed by the processor 260.

Although not illustrated, the processor 260 may form part of the transmitter 252 and/or the receiver 254. Also, although not illustrated, the processor 260 may implement the scheduler 253. Although not illustrated, the memory 258 may form part of the processor 260.

The processor 260, the scheduler 253, and the processing components of the transmitter 252 and the receiver 254 may each be implemented by the same or different one or more processors that are configured to execute instructions stored in a memory, e.g. in memory 258. Alternatively, some or all of the processor 260, the scheduler 253, and the processing components of the transmitter 252 and the receiver 254 may be implemented using dedicated circuitry, such as an FPGA, a GPU, or an ASIC.

The NT-TRP 172 is illustrated as a drone only as an example. The NT-TRP 172 may be implemented in any suitable non-terrestrial form. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110, processing an uplink transmission received from the ED 110, preparing a transmission for backhaul transmission to T-TRP 170, and processing a transmission received over backhaul from the T-TRP 170. Processing operations related to preparing a transmission for downlink or backhaul transmission may include operations such as encoding, modulating, precoding (e.g. MIMO precoding), transmit beamforming, and generating symbols for transmission. Processing operations related to processing received transmissions in the uplink or over backhaul may include operations such as receive beamforming, and demodulating and decoding received symbols. In some embodiments, the processor 276 implements the transmit beamforming and/or receive beamforming based on beam direction information (e.g. BAI) received from T-TRP 170. In some embodiments, the processor 276 may generate signaling, e.g. to configure one or more parameters of the ED 110. In some embodiments, the NT-TRP 172 implements physical layer processing, but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or receiver 274. Although not illustrated, the memory 278 may form part of the processor 276.

The processor 276 and the processing components of the transmitter 272 and the receiver 274 may each be implemented by the same or different one or more processors that are configured to execute instructions stored in a memory, e.g. in memory 278. Alternatively, some or all of the processor 276 and the processing components of the transmitter 272 and the receiver 274 may be implemented using dedicated circuitry, such as a programmed FPGA, a GPU, or an ASIC. In some embodiments, the NT-TRP 172 may actually be a plurality of NT-TRPs that are operating together to serve the ED 110, e.g. through coordinated multipoint transmissions.

The T-TRP 170, the NT-TRP 172, and/or the ED 110 may include other components, but these have been omitted for the sake of clarity.

One or more steps of the embodiment methods provided herein may be performed by corresponding units or modules, according to FIG. 4.

Referring to FIG. 4, as an illustrative example of units or modules in a device, such as in the ED 110, in the T-TRP 170, or in the NT-TRP 172. For example, a signal may be transmitted by a transmitting unit or a transmitting module. For example, a signal may be transmitted by a transmitting unit or a transmitting module. A signal may be received by a receiving unit or a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be an integrated circuit, such as a programmed FPGA, a GPU, or an ASIC. It will be appreciated that where the modules are implemented using software for execution by a processor for example, they may be retrieved by a processor, in whole or part as needed, individually or together for processing, in single or multiple instances, and that the modules themselves may include instructions for further deployment and instantiation.

Additional details regarding the EDs 110, T-TRP 170, and NT-TRP 172 are known to those of skill in the art. As such, these details are omitted here.

For ease of description, an apparatus that transmits data is herein-after referred to as a transmitting apparatus and an apparatus that receives the data is herein-after referred to as a receiving apparatus. The receiving apparatus may be referred to as ED 110 for a downlink transmission, and T-TRP 170 or NT-TRP 172 for an uplink transmission. The transmitting apparatus may be referred to as T-TRP 170 or NT-TRP 172 for a downlink transmission, and ED 110 for an uplink transmission. However, limitation is not made herein.

A data can be represented by a transport block (TB) in a physical layer. Further, the TB can be segmented into multiple code blocks (CBs) and each CB can then be encoded by a forward error correction (FEC) code for transmission. For example, a low density parity check (LDPC) code is used as the FEC code. The LDPC is a systematic code in which a CB consists of both information/systematic bits and parity/check bits. The information/systematic bits represent the data, and the parity/check bits represent redundancy bits which are calculated and added based on the LDPC for error correction. Hereafter, an information bit is used as an example, and the information bit may be referred to as a systematic bit. Similarly, a parity bit is used as an example, and the parity bit may be referred to as a check bit.

In a wireless communication, a retransmission is required if data transmitted in an initial transmission was not decoded successfully.

In one example, a hybrid automatic repeat request (HARQ) incremental redundancy (IR) scheme may be used for the retransmission. Specifically, each CB is first encoded by LDPC at a mother code rate (CR) to obtain a mother codeword. Based on a CR and a number of corresponding transmission resources, a subset of bits of the mother codeword, which may be referred as a redundancy version (RV), is selected for transmission. For example, four RVs, namely RV0, RV1, RV2 and RV3, are generated from the mother codeword, each RV consists of different subset of bits of the mother codeword, some subset of bits may be overlapped between RVs, and limitation is not made herein. The RV0 and the RV3 generally include information bits, while the RV1 and the RV2 generally include parity bits. In an initial transmission, the RV0 may be transmitted as the RV0 including all information bits. If the RV0 is not decoded successfully at a receiving apparatus, the RV2 may be selected for retransmission as the RV2 generally including most of parity bits, and that the RV0 is not decoded successfully at the receiving apparatus may be due to too high CR of the RV0 for a channel condition. After receiving the RV2, the receiving apparatus may combine coded bits of the RV0 and the RV2 to form a longer codeword with a reduced CR and decode it again. As the RV2 has some parity bits that are not included in the RV0, after combining the RV0 and the RV2, the longer codeword has more chances to be decoded successfully than that of the initial transmission.

In this HARQ IR scheme, the receiving apparatus can feedback a CB index, a CBG index or a TB index if that CB-level, CBG-level or TB-level feedback is used, respectively. For each erroneous CB, a transmitting apparatus can generate and retransmit another RV. The receiving apparatus then combines RVs received in the initial transmission and retransmission to form a longer codeword with a reduced CR, which results in better decoding performance. However, this scheme has a high feedback overhead if CB-level or CBG-level feedback is used. Further, the receiving apparatus combines RVs received in the initial transmission and retransmission to form a longer codeword with a reduced CR for joint decoding, which increases decoding complexity due to the long codeword.

In another example, a cross-CB coding scheme may be used for the retransmission/HARQ. In the cross-CB coding scheme, a cross-CB coded block is formed by the coded bits that are generated from information bits selected from across two or more different CBs. A cross-CB coded block may be generated by, for example, selecting information bits from across two or more CBs, then encoding (e.g., using a FEC code, such as low-density parity-check (LDPC) code) or otherwise combining (e.g., using XOR, linear combination, etc.) the selected information bits to obtain the cross-CB coded block. In some examples, a cross-CB coded block may be referred to as a cross-CB coded block, a vertical code block, or a vertical check block (VCB). The cross-CB coded block may be referred to as “vertical” merely in order to distinguish from a “horizontal” code block that is generated using information bits of a single CB by a FEC code. Thus, the vertical and horizontal orientations are arbitrary terms used for differentiation, rather than implying any physical or conceptual orientation. In the cross-CB coding scheme, after an initial transmission, a set of vertical blocks from columns of CBs are encoded to generate vertical check blocks (VCBs) by using FEC methods such as LDPC, Polar code or Turbo code, and the VCBs may be retransmit to a receiving apparatus. In the initial transmission, the CBs may be encoded by a systematic code in which each CB includes both information bits and parity bits. In this case, data is represented in the information bits, and the VCBs are determined from the information parts of the CBs. Alternatively, if the CBs are encoded by a non-systematic code in which the data are not included, the VCBs are determined from the entire CBs. At the receiving apparatus, for both systematic code and non-systematic code, the CBs from the initial transmission and the VCBs from a retransmission are jointly decoded via soft-combining to effectively obtain the data.

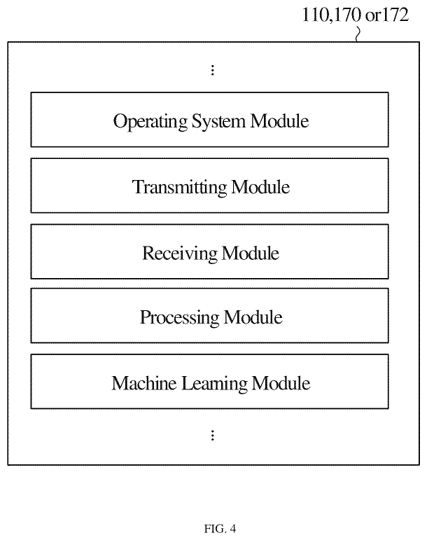

Referring to FIG. 5, an illustration of generating 4 VCBs from 4 CBs in an initial transmission is shown. As shown in FIG. 5, a systematic code is adopted at CBs, so each CB consists of information bits and parity bits. As aforementioned, the information bits basically represent data, while parity bits represent redundancy bits added by a FEC method for error correction in the initial transmission. Similarly, a VCB includes the parity bits generated by a FEC method in a retransmission. In this example, the information bits of CBn, n=1, . . . , 4, are divided into 4 subblocks {SBn1, SBn2, SBn3, SBn4}, and VCBm, m=1, . . . , 4, are generated from 4 SBs {SB1m, SB2m, SB3m, SB4m}.

In this cross-CB coding scheme, VCBs which are generated from all information bits of CBs are retransmitted. At the receiving apparatus, Turbo iterative decoding may be performed in which soft information between decoders of CBs and VCBs are exchanged in multiple iterations to improve decoding performance. Decoding complexity of this scheme may be high due to the Turbo iterative decoding, especially for a large number of CBs and VCBs.

In another example, an erasure outer code scheme may be used for the retransmission/HARQ. The main idea of the erasure outer code scheme is that, a transmitting apparatus uses an erasure code to generate the same number of parity check blocks (PCBs) from all erroneous CBs for retransmission based on feedback of a number of erroneous CBs indicated by a receiving apparatus. At the receiving apparatus, such PCBs can help to recover erroneous CBs in initial transmission.

In this erasure outer codes scheme, the receiving apparatus needs to feedback a number of erroneous CBs to the transmitting apparatus for retransmission, and thus feedback overhead may be high. Further, since an outer code is an erasure code, its performance may deteriorate in non-erasure channels (e.g., fading channels in wireless communications).

In another example, an incremental freezing (IF) scheme may be used for the retransmission/HARQ. The main idea of the incremental freezing scheme is that, if information bits are not successfully decoded in initial transmission, a subset of the information bits can be retransmitted. A CR of a retransmission is lower than a CR of previous transmission, so information bits in retransmission have a higher chance to be decoded successfully. If the information bits in the retransmissions are decoded successfully, these information bits can be considered as frozen bits (i.e., be known at decoders) for initial transmission, which allows the rest of information bits in the initial transmission can be decoded at a lower CR.

In this application, a cross-CB coding scheme and an IF scheme are employed for retransmission/HARQ using LDPC. For example, a retransmission scheme in this application can be refer to as a cross-CB IF coding scheme. Specifically, a VCB in current retransmission can be generated by LDPC encoding a part of information bits of previous (re) transmission, and a receiving apparatus can decode a VCB in current retransmission, and if the VCB is decoded successfully, the part of information bits can be considered as frozen bits (i.e., be known at decoders), which allows the rest of information bits in the previous (re) transmission can be decoded at a lower CR. Thus, compared to traditional HARQ IR that requires to decode a long codeword, the cross-CB IF coding scheme can offer lower decoding complexity by decoding multiple short codewords.

The following describes the embodiments of this application in detail with reference to the accompanying drawings.

In the embodiments of this application, “and/or” describes an association relationship between associated objects and represents that three relationships may exist. For example, A and/or B may represent the following three cases: only A exists, both A and B exist, and only B exists. The character “/” generally indicates an “or” relationship between the associated objects. For example, “A/B” means that A and B are interchangeably equivalent.

In the embodiments of this application, “at least one” means one or more. “at least one of A and B”, similar to “A and/or B”, describes an association relationship between associated objects and represents that three relationships may exist. For example, at least one of A and B may represent the following three cases: only A exists, both A and B exist, and only B exists.

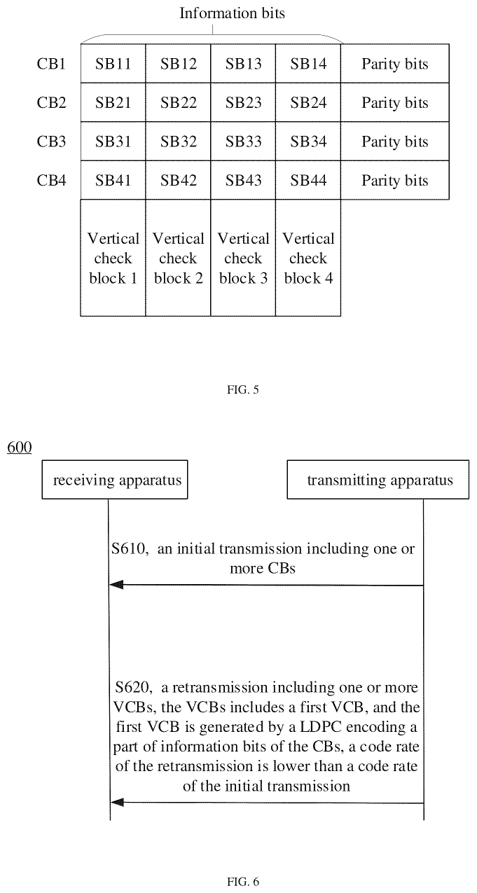

Referring to FIG. 6, FIG. 6 is a schematic flowchart of a communication method 600 according to an embodiment of this application.

At S610, a transmitting apparatus transmits an initial transmission including one or more CBs. Correspondingly, a receiving apparatus receives the initial transmission, namely, the receiving apparatus receives the CBs. Further the receiving apparatus can decode the CBs.

As described above, data can be represented by a TB in the physical layer, further, the TB can be segmented into multiple CBs and each CB can then encoded by a FEC (e.g., LDPC) code for transmission, therefore, at S610, the transmitting apparatus actually transmits the initial transmission including data.

The transmitting apparatus is a UE, or a component (e.g., a chip, a circuit, or a processing system) configured in the UE; or the transmitting apparatus is a base station, or a component (e.g., a chip, a circuit, or a processing system) configured in the base station.

The receiving apparatus is a base station, or a component (e.g., a chip, a circuit, or a processing system) configured in the base station; or the receiving apparatus is a UE, or a component (e.g., a chip, a circuit, or a processing system) configured in the UE.

At S620, the transmitting apparatus transmits a retransmission including one or more VCBs, where the VCBs include a first VCB, and the first VCB is generated by encoding, according to or using the LDPC code, a part of information bits of the CBs, where a code rate of the retransmission is lower than a code rate of the initial transmission. Correspondingly, the receiving apparatus receives the retransmission.

In general, a retransmission is required if data is not successfully decoded in the initial transmission. Specifically, the receiving apparatus decodes the CBs received, and if the CBs are not successfully decoded, then the transmitting apparatus may transmit the retransmission. However, limitation is not made herein. For example, no matter whether the data in the initial transmission is decoded successfully or not, the transmitting apparatus can transmit the retransmission.

The first VCB can include one or more VCBs. For example, the first VCB can be referred to as the first VCB set or the first set of VCBs.

The transmitting apparatus may transmit one or more retransmissions, each retransmission may include one or more VCBs, and a code rate of each retransmission is lower than a code rate of the initial transmission. Further, the one or more retransmissions include a first retransmission including the first VCB. The first retransmission represents the 1^{st} retransmission after the initial transmission. Further, if the transmitting apparatus transmits multiple retransmissions, then a code rate of each retransmission is lower than a code rate of previous transmission or retransmission.

In some embodiments, the method 600 further includes: the transmitting apparatus receives first feedback indicating whether the CBs transmitted in the initial transmission are decoded successfully.

In a possible implementation, the first feedback is negative acknowledgement (NACK) feedback, e.g., HARQ-NACK, which indicates the CBs transmitted in the initial transmission are not decoded successfully, in other words, the NACK feedback indicates data transmitted in the initial transmission are not decoded successfully.

In response the NACK feedback, the transmitting apparatus transmits a retransmission. Specifically, the transmitting apparatus transmits the first retransmission including the first VCB, and the first VCB is generated by encoding, according to or using an LDPC code, a part of information bits of the CBs. The first VCB can include one or more VCBs.

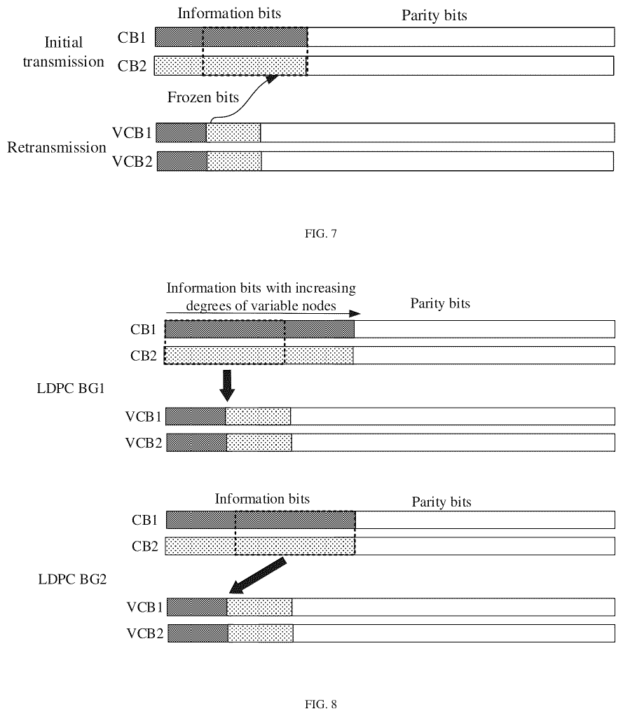

Referring to FIG. 7, FIG. 7 is an example of a retransmission scheme of this application. Assuming the one or more CBs include CB1 and CB2, the first VCB includes VCB1 and VCB2. As shown in FIG. 7, a part of information bits of both the CB1 and CB2 are retransmitted via the VCB1 and VCB2.

Correspondingly, the receiving apparatus receives the first retransmission. Further, the first VCB can be first decoded. Specifically, the part of information bits of the CBs is first combined in information bits of the first VCB. The first VCB after combining is then decoded. If the first VCB is decoded successfully, corresponding information bits can be considered as frozen bits (i.e., such information bits are known in the decoding process) to reduce a code rate in LDPC decoders of the CBs in the initial transmission. In some cases, even if the first VCB is not decoded successfully, the extrinsic information of common information bits between the CBs and the first VCB can be passed from decoders of the first VCB to decoders of the CBs, which can improve decoding performance of the CBs.

If the first feedback is acknowledgement (ACK) feedback, e.g., HARQ-ACK, which indicates the CBs transmitted in the initial transmission are decoded successfully, then the transmitting apparatus does not need to transmit the retransmission.

The above implementation is only an example, and limitation is not made herein. For example, if the transmitting apparatus does not receive ACK feedback within a certain period of time, then the transmitting apparatus can determine the data in the initial transmission is not decoded successfully, and transmit the first retransmission.

Further, in some embodiments, the method 600 further includes: the transmitting apparatus receives second feedback indicating whether the first VCB transmitted in the first retransmission was decoded successfully, in other words, the second feedback indicates whether the data transmitted in the initial transmission was decoded successfully.

In a possible implementation, the second feedback is NACK feedback, e.g., HARQ-NACK, which indicates the first VCB transmitted in the first retransmission was not decoded successfully, in other words, the NACK feedback indicates the data transmitted in the initial transmission was still not decoded successfully.

In response the NACK feedback, the transmitting apparatus transmits a retransmission. Specifically, the transmitting apparatus transmits a second retransmission including a second VCB, and the second VCB is generated by encoding, according to or using an LDPC code, a part of information bits of the first VCB. The second VCB can include one or more VCBs.

Correspondingly, the receiving apparatus receives the second retransmission. Further, the second VCB can be first decoded. If the second VCB is decoded successfully, corresponding information bits in the second VCBs can be considered as frozen bits (i.e., such information bits are known in the decoding process of the first VCB), which can effectively reduce a code rate of the first VCB, and increase a chance of the first VCB to be decoded successfully. Then the first VCB can be decoded. If the first VCB is decoded successfully, corresponding information bits in the first VCBs can be considered as frozen bits (i.e., such information bits are known in the decoding process of the CBs), which can effectively reduce a code rate of the CBs, and improve decoding performance of the CBs.

If the second feedback is ACK feedback, e.g., HARQ-ACK, which indicates the first VCB transmitted in the first retransmission was decoded successfully, then the transmitting apparatus may stop transmitting the retransmission, namely, the transmitting apparatus may not transmit the second retransmission.

The above implementation is only an example, and limitation is not made herein. For example, if the transmitting apparatus does not receive ACK feedback within a certain period of time, then the transmitting apparatus can determine the first VCB in the first retransmission is not decoded successfully, and transmit the second retransmission.

A VCB in a current retransmission can be generated by encoding, according to or using an LDPC code, a part of information bits of previous (re) transmission. For simplicity and conciseness, the following examples describe various retransmission schemes in relation to the generation of the first VCB; however, it should be understood that these same retransmission schemes also may be used with other (second, etc.) VCBs.

In one example embodiment, the part of the information bits corresponds to variable nodes with lower degrees. Namely, the part of information bits of the CBs which is used to generate the first VCB includes information bits corresponding to variable nodes of each CB, where degrees of the variable nodes are lower than a threshold. For example, the part of information bits corresponds to variable nodes with the lowest degrees.

Specifically, in an LDPC message passing decoder, information bits correspond to variable nodes with different degrees, and information bits corresponding to variable nodes with higher degrees are more likely to be decoded successfully since they receive more information from adjacent check nodes. As a result, information bits corresponding to variable nodes with lower degrees can be retransmitted.

Some example LDPC codes have two base graphs (BGs) respectively referred to as BG1 and BG2. For example, information bits corresponding to variable nodes with lower degrees can be applied to BG1 and/or BG2.

Referring to FIG. 8, FIG. 8 is another example of a retransmission scheme of this application. As shown in FIG. 8, there are two CBs respectively referred to as CB1 and CB2, and the first VCB includes VCB1 and VCB2, and a part of information bits of the CB1 and CB2 are retransmitted via the VCB1 and VCB2. Assuming information bits of each CB are ordered with increasing degrees of variable nodes, according to example above for selecting the part of the information bits corresponding to variable nodes with lower degrees, bits located in beginning-most positions may be determined (or selected) for retransmission. As shown in FIG. 8, for example, for BG1, the VCB1 and VCB2 are generated by encoding information bits located in beginning-most positions of both CB1 and CB2.

According to the example above for selecting the part of the information bits corresponding to variable nodes with lower degrees, the part of information bits of the first VCB which is used to generate the second VCB can also include information bits corresponding to variable nodes of the first VCB (or each VCB of the first VCB), where degrees of the variable nodes are lower than a threshold, for example, the part of information bits of the first VCB which is used to generate the second VCB can also include information bits corresponding to variable nodes with lowest degrees.

In another example embodiment, the part of the information bits corresponds to ending-most positions. Namely, the part of information bits of the CBs which is used to generate the first VCB includes information bits corresponding to ending-most positions of each CB.

Specifically, at the BG level, some ending-most variable nodes can be eliminated when the codeword is shortened, while the BG after lifting can still offer good decoding performance.

For example, information bits corresponding to ending-most positions can be applied to BG1 and/or BG2. As shown in FIG. 8, for example, for BG2, the VCB1 and VCB2 are generated by encoding information bits located in ending-most positions of both CB1 and CB2.

According to the example above for selecting the part of the information bits corresponding to ending-most positions, the part of information bits of the first VCB which is used to generate the second VCB can also include information bits corresponding to ending-most positions of the first VCB (or each VCB of the first VCB).

The different embodiments above for selecting the part of the information bits are non-limiting examples, which are described herein to illustrate the flexibility of the cross-CB coded block retransmission scheme. Further variations are also possible. For example, in another embodiment, a part of the information bits corresponds to beginning-most positions. Namely, the part of information bits of the CBs which is used to generate the first VCB includes bits corresponding to beginning-most positions of each CB.

Further, the scheme of which information bits are to be retransmitted can be pre-defined, such as being pre-defined in a standard. For example, a manner of selecting a part of information bits for each LDPC BG (e.g. based on degrees of variable nodes for BG1 or ending-most variable nodes for BG2) can be pre-defined.

In retransmission/HARQ, multiple retransmissions may be required for all CBs to be decoded successfully at the receiver. In general, a code rate of next retransmission is lower than a code rate of current (re) transmission. The following describes rate determination for the case of multiple retransmissions. That rate determination here refers to determining a code rate to encode VCBs and the number of corresponding selected information bits in each CB.

In some embodiments, the retransmission comprises the i^{th} retransmission and the j^{th} retransmission, i>j, and a code rate of the i^{th} retransmission satisfies Form 1.

$$\frac{{K}_{j} - {K}_{i}}{{N}_{j} - {K}_{i}} < \frac{{K}_{i}}{{N}_{i}} : \qquad Form 1$$

The parameters in Form 1 are explained below.

$$\frac{{K}_{i}}{{N}_{i}}$$

represents the code rate of the i^{th} retransmission where Kᵢ represents the number of information bits in each CB of the i^{th} retransmission, and Nᵢ represents code bits of the i^{th} retransmission. Kⱼ represents the number of information bits in each CB of the j^{th} retransmission. Nⱼ represents code bits of the j^{th} retransmission.

In general, for the i^{th} retransmission, the transmitting apparatus can retransmit a selected portion of information bits in the previous (i−1)^{th} (re) transmission. In a possible implementation, j=i−1. For example, the j^{th} retransmission is the 1^{st} retransmission, and the i^{th} retransmission is the 2^{nd} retransmission.

In some embodiments, Kᵢ satisfies Form 2.

$${K}_{i} > \frac{1}{2} ( {N}_{i} + {N}_{i - 1} - \sqrt{{( {N}_{i} + {N}_{i - 1} )}^{2} - 4 {K}_{i - 1} {N}_{i}} ) : \qquad Form 2$$

Thus, if a retransmission is decoded successfully, the previous (re) transmission can also be decoded.

Further, if it is not possible to find Kᵢ satisfying Form 2, the transmitting apparatus can select Kᵢ that is closest to

$$\frac{1}{2} ( {N}_{i} + {N}_{i - 1} - \sqrt{{( {N}_{i} + {N}_{i - 1} )}^{2} - 4 {K}_{i - 1} {N}_{i}} ) .$$

In some embodiments, the transmitting apparatus transmits a first indication indicating a code rate of the retransmission and/or the initial transmission. Correspondingly, a receiving apparatus receives the first indication. For example, the transmitting apparatus transmits the first indication indicating a code rate of the i^{th} retransmission, namely, the first indication indicates Kᵢ/Nᵢ.

The first indication can be carried by a control channel signal, e.g., downlink control information (DCI), uplink control information (UCI), or sidelink control information (SCI).

In some embodiments, the transmitting apparatus transmits a second indication indicating a modulation and coding scheme (MCS) of the retransmission and/or the initial transmission. Correspondingly, a receiving apparatus receives the second indication. Where the second indication can be carried by a control channel signal, e.g., DCI, UCI, or SCI. The first indication and the second indication may be carried by the same signal or different signals.

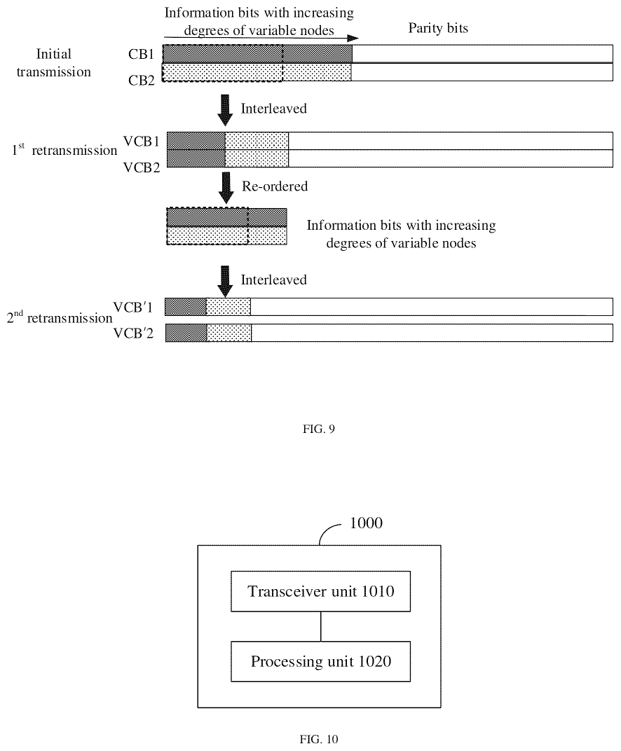

Each embodiment is described above, and a specific example is given in combination with FIG. 9.

Referring to FIG. 9, FIG. 9 is an example of a cross-CB IF coding scheme with two retransmissions of this application.

As shown in FIG. 9, assuming there are retransmissions respectively called as 1^{st} retransmission and 2^{nd} retransmission. In each retransmission, the transmitting apparatus can determine a part of information bits which are retransmitted based on Manner #1, namely, information bits corresponding to variable nodes with lower degrees are retransmitted. Specifically, information bits of each CB are first reordered with increasing degrees of variable nodes, and information bits located in beginning-most positions of such reordered information bits are selected to generate VCBs (that is VCB1 and VCB2) for the 1^{st} retransmission. Similarly, information bits of each VCB are first reordered with increasing degrees of variable nodes, and information bits located in beginning-most positions of such reordered information bits are selected to generate VCBs (that is VCB′1 and VCB′2) for the 2^{nd} retransmission. As shown in FIG. 9. before forming the VCBs, interleaved operation can be performed in selected information bits to evenly distribute bits corresponding to variable nodes with different degrees to the VCBs. For example, a subblock interleaver or random interleaver can be chosen to preform interleaved operation.

At the receiving apparatus, VCB′1 and VCB′2 in the 2^{nd} retransmission are first decoded. If VCB′1 and/or VCB′2 are decoded successfully, corresponding information bits of VCB′1 and/or VCB′2 can be considered as frozen bits, namely, the corresponding information bits of VCB′1 and/or VCB′2 are known, in decoders of VCB1 and VCB2. This effectively reduces code rates of both VCB1 and VCB2, and increase the chance of VCB1 and VCB2 to be decoded successfully. If VCB1 and/or VCB2 are decoded successfully, corresponding information bits can be considered as frozen bits in decoders of CB1 and CB2, which can reduce code rates of both CB1 and CB2 and subsequently improve the decoding performance of both CB1 and CB2.

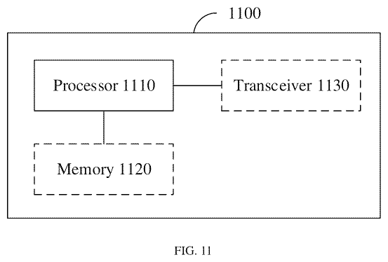

The methods according to embodiments of this application are described above in detail with reference to FIGS. 6-9. The apparatuses provided in embodiments of this application are described below in detail with reference to FIGS. 10-11. The description of apparatus embodiments corresponds to the description of the method embodiments. Therefore, for content that is not described in detail, refer to the foregoing method embodiments. For brevity, details are not described herein again.

Referring to FIG. 10, a schematic block diagram of a communication apparatus according to an embodiment of this application is shown. The communication apparatus 1000 includes a transceiver unit 1010 and a processing unit 1020. The transceiver unit 1010 may implement a corresponding communication function, and the processing unit 1020 is configured to perform data processing. The transceiver unit 1010 may also be referred to as a communication interface or a communication unit.

In some embodiments, the communication apparatus 1000 may further include a storage unit. The storage unit may be configured to store instructions and/or data. The processing unit 1020 may read instructions and/or data in the storage unit, to enable the communication apparatus to implement the foregoing method embodiments.

The communication apparatus 1000 may be configured to perform actions performed by the transmitting apparatus in the foregoing method embodiments. The transceiver unit 1010 is configured to perform communicating-related (e.g., receiving/transmitting-related) operations on the transmitting apparatus side in the foregoing method embodiments. The processing unit 1020 is configured to perform processing-related operations on the transmitting apparatus side in the foregoing method embodiments.

The communication apparatus 1000 may implement steps or procedures performed by the transmitting apparatus in FIGS. 6-9 according to embodiments of this application. The communication apparatus 1000 may include units configured to perform the method performed by the transmitting apparatus in FIGS. 6-9. In addition, the units in the communication apparatus 1000 and the foregoing other operations and/or functions are separately used to implement corresponding procedures in FIGS. 6-9.

Alternatively, the communication apparatus 1000 may be configured to perform actions performed by the receiving apparatus in the foregoing method embodiments. The transceiver unit 1010 is configured to perform communicating-related (e.g., receiving/transmitting-related) operations on the receiving apparatus side in the foregoing method embodiments. The processing unit 1020 is configured to perform processing-related operations on the receiving apparatus side in the foregoing method embodiments.

The communication apparatus 1000 may implement steps or procedures performed by the receiving apparatus in FIGS. 6-9 according to embodiments of this application. The communication apparatus 1000 may include units configured to perform the method performed by the receiving apparatus in FIGS. 6-9. In addition, the units in the communication apparatus 1000 and the foregoing other operations and/or functions are separately used to implement corresponding procedures in FIGS. 6-9.

A specific process in which the units perform the foregoing corresponding steps is described in detail in the foregoing method embodiments. For brevity, details are not described herein again.

Referring to FIG. 11, a schematic block diagram of another communication apparatus according to an embodiment of this application is shown. The communication apparatus 1100 includes a processor 1110. The processor 1110 is coupled to a memory 1120. The memory 1120 is configured to store a computer program or instructions and/or data. The processor 1110 is configured to execute the computer program or instructions and/or data stored in the memory 1120, so that the methods in the foregoing method embodiments are executed.

In some embodiments, the communication apparatus 1100 includes one or more processors 1110.

In an example, as shown in FIG. 11, the communication apparatus 1100 may further include the memory 1120.

In some embodiments, the communication apparatus 1100 may include one or more memories 1120.

In an example, the memory 1120 may be integrated with the processor 1110, or disposed separately from the processor 1110.

In an example, as shown in FIG. 11, the communication apparatus 1100 may further include a transceiver 1130, where the transceiver 1130 is configured to receive and/or transmit a signal. For example, the processor 1110 may be configured to control the transceiver 1130 to receive and/or transmit a signal.

In some embodiments, the communication apparatus 1100 may be a transmitting apparatus, e.g., a UE or a component (e.g., a chip, a circuit, or a processing system) that can be configured in the UE, or a base station or a component (e.g., a chip, a circuit, or a processing system) that can be configured in the base station.

In a solution, the communication apparatus 1100 is configured to perform the operations performed by the transmitting apparatus in the foregoing method embodiments.

For example, the processor 1110 may be configured to perform a processing-related operation performed by the transmitting apparatus in the foregoing method embodiments, and the transceiver 1130 may be configured to perform a communicating-related (e.g., receiving/transmitting-related) operation performed by the transmitting apparatus in the foregoing method embodiments.

In some embodiments, the communication apparatus 1100 may be a receiving apparatus, e.g., a UE or a component (e.g., a chip, a circuit, or a processing system) that can be configured in the UE, or a base station or a component (e.g., a chip, a circuit, or a processing system) that can be configured in the base station.

In a solution, the communication apparatus 1100 is configured to perform the operations performed by the receiving apparatus in the foregoing method embodiments.

For example, the processor 1110 may be configured to perform a processing-related operation performed by the receiving apparatus in the foregoing method embodiments, and the transceiver 1130 may be configured to perform a communicating-related (e.g., receiving/transmitting-related) operation performed by the receiving apparatus in the foregoing method embodiments.

An embodiment of this application further provides a computer-readable storage medium. The computer-readable storage medium stores computer instructions used to implement the method performed by the transmitting apparatus or the method performed by the receiving apparatus in the foregoing method embodiments.

For example, when the computer program is executed by a computer, the computer may be enabled to implement the method performed by the transmitting apparatus or the method performed by the receiving apparatus in the foregoing method embodiments.

An embodiment of this application further provides a computer program product including instructions. When the instructions are executed by a computer, the computer is enabled to implement the method performed by the transmitting apparatus or the method performed by the receiving apparatus in the foregoing method embodiments.

An embodiment of this application further provides a communication system. The communication system includes the transmitting apparatus and the receiving apparatus in the foregoing embodiments.

For explanations and beneficial effects of related content of any communication apparatus provided above, refer to a corresponding method embodiment provided above. Details are not described herein again.

The processor mentioned in embodiments of this application may be a central processing unit (CPU). The processor may further be another general-purpose processor, a digital signal processor (DSP), an application-specific integrated circuit (ASIC), a field programmable gate array (FPGA), or another programmable logic device, a discrete gate, a transistor logic device, a discrete hardware component, or the like. The general-purpose processor may be a microprocessor, or the processor may be any conventional processor or the like.

The memory mentioned in embodiments of this application may be a volatile memory or a non-volatile memory, or may include a volatile memory and a non-volatile memory. The non-volatile memory may be a read-only memory (ROM), a programmable read-only memory (programmable ROM, PROM), an erasable programmable read-only memory (erasable PROM, EPROM), an electrically erasable programmable read-only memory (electrically EPROM, EEPROM), or a flash memory. The volatile memory may be a random access memory (RAM). For example, the RAM may be used as an external cache. By way of example but not limitation, the RAM may include a plurality of forms such as the following: a static random access memory (static RAM, SRAM), a dynamic random access memory (dynamic RAM, DRAM), a synchronous dynamic random access memory (synchronous DRAM, SDRAM), a double data rate synchronous dynamic random access memory (double data rate SDRAM, DDR SDRAM), an enhanced synchronous dynamic random access memory (enhanced SDRAM, ESDRAM), a synchlink dynamic random access memory (synchlink DRAM, SLDRAM), and a direct rambus random access memory (direct rambus RAM, DR RAM).

It should be noted that when the processor is a general-purpose processor, a DSP, an ASIC, an FPGA, another programmable logic device, a discrete gate or a transistor logic device, or a discrete hardware component, the memory (storage module) may be integrated into the processor.

It should be further noted that the memory described in this specification is intended to include, but is not limited to, these memories and any other memory of a suitable type.

A person of ordinary skill in the art may be aware that, in combination with the examples described in embodiments disclosed in this specification, units and methods may be implemented by electronic hardware or a combination of computer software and electronic hardware. Whether the functions are performed by hardware or software depends on particular applications and design constraints of the technical solutions. A person skilled in the art may use different methods to implement the described functions for each particular application, but it should not be considered that the implementation goes beyond the protection scope of this application.

It may be clearly understood by a person skilled in the art that, for the purpose of convenient and brief description, for a detailed working process of the foregoing apparatus and unit, refer to a corresponding process in the foregoing method embodiment. Details are not described herein again.

In the several embodiments provided in this application, the disclosed apparatuses and methods may be implemented in other manners. For example, the described apparatus embodiment is merely an example. For example, division into the units is merely logical function division and may be other division in an actual implementation. For example, a plurality of units or components may be combined or integrated into another system, or some features may be ignored or not performed. In addition, the displayed or discussed mutual couplings or direct couplings or communication connections may be implemented through some interfaces. The indirect couplings or communication connections between the apparatuses or units may be implemented in electronic forms, mechanical forms, or other forms.

The units described as separate parts may or may not be physically separate, and parts displayed as units may or may not be physical units, may be located in one position, or may be distributed on a plurality of network units. Some or all of the units may be selected based on an actual requirement to implement the solutions provided in this application.

In addition, function units in embodiments of this application may be integrated into one unit, or each of the units may exist alone physically, or two or more units may be integrated into one unit.

All or some of the foregoing embodiments may be implemented by using software, hardware, firmware, or any combination thereof. When the software is used to implement embodiments, all or a part of embodiments may be implemented in a form of a computer program product. The computer program product includes one or more computer instructions. When the computer program instructions are loaded and executed on the computer, the procedures or functions according to embodiments of this application are all or partially generated. The computer may be a general-purpose computer, a special-purpose computer, a computer network, or another programmable apparatus. For example, the computer may be a personal computer, a server, a network device, or the like. The computer instructions may be stored in a computer-readable storage medium or may be transmitted from a computer-readable storage medium to another computer-readable storage medium. For example, the computer instructions may be transmitted from a website, computer, server, or data center to another website, computer, server, or data center in a wired (for example, a coaxial cable, an optical fiber, or a digital subscriber line (DSL)) or wireless (for example, infrared, radio, and microwave, or the like) manner. The computer-readable storage medium may be any usable medium accessible by the computer, or a data storage device, for example, a server or a data center, integrating one or more usable media. The usable medium may be a magnetic medium (for example, a floppy disk, a hard disk, or a magnetic tape), an optical medium (for example, a DVD), a semiconductor medium (for example, an SSD), or the like. For example, the usable medium may include but is not limited to any medium that can store program code, such as a USB flash drive, a removable hard disk, a ROM, a RAM, a magnetic disk, or an optical disc.

The foregoing description is merely a specific implementation of this application, but is not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims and the specification.

What is claimed is:

1. A method, comprising:
transmitting an initial transmission comprising multiple code blocks (CBs); and
transmitting a retransmission comprising one or more cross-CB coded blocks, wherein the cross-CB coded blocks comprise a first cross-CB coded block, and the first cross-CB coded block is generated by encoding, according to a low density parity check (LDPC) code, a part of information bits of the multiple CBs, and wherein a code rate of the retransmission is lower than a code rate of the initial transmission.

2. The method of claim 1, wherein the part of information bits of the multiple CBs comprises one or more of:
bits corresponding to variable nodes of each CB of the multiple CBs, wherein degrees of the variable nodes are less than a threshold;
bits corresponding to ending-most positions of each CB of the multiple CBs; or
bits corresponding to beginning-most positions of each CB of the multiple CBs.

3. The method of claim 1, wherein the retransmission comprises a first retransmission including the first cross-CB coded block, the retransmission further comprises a second retransmission including a second cross-CB coded block, and the second cross-CB coded block is generated by encoding, according to the LDPC code, a part of information bits of the first cross-CB coded block.

4. The method of claim 1, wherein the retransmission comprises an i^{th} retransmission and a j^{th} retransmission, wherein i>j, and a code rate of the i^{th} retransmission satisfies:
$$\frac{{K}_{j} - {K}_{i}}{{N}_{j} - {K}_{i}} < \frac{{K}_{i}}{{N}_{i}}$$
wherein:
$$\frac{{K}_{i}}{{N}_{i}}$$
represents a code rate of the i^{th} retransmission;
Kᵢ represents a number of information bits in each CB of the i^{th} retransmission;
Nᵢ represents code bits of the i^{th} retransmission;
Kⱼ represents a number of information bits in each CB of the j^{th} retransmission; and
Nⱼ represents code bits of the j^{th} retransmission.

5. The method of claim 1, further comprising:
performing an interleaving operation in the part of information bits of the multiple CBs; and
generating the first cross-CB coded block by encoding, according to the LDPC code, the part of the information bits of the multiple CBs.

6. A method, comprising:
receiving an initial transmission comprising multiple code blocks (CBs); and
receiving a retransmission comprising one or more cross-CB coded blocks, wherein the cross-CB coded blocks comprises a first cross-CB coded block, and the first cross-CB coded block is generated by encoding, according to a low density parity check (LDPC) code, a part of information bits of the multiple CBs, and wherein a code rate of the retransmission is lower than a code rate of the initial transmission.

7. The method of claim 6, wherein the method further comprises:
decoding the first cross-CB coded block of the retransmission; and
after the decoding the first cross-CB coded block, decoding the multiple CBs of the initial transmission based on decoded results of the first cross-CB coded block.

8. The method of claim 6, wherein the part of information bits of the multiple CBs comprises one or more of:
bits corresponding to variable nodes of each CB of the multiple CBs, wherein degrees of the variable nodes are less than a threshold;
bits corresponding to ending-most positions of each CB of the multiple CBs; or
bits corresponding to beginning-most positions of each CB of the multiple CBS.

9. The method of claim 6, wherein the retransmission comprises a first retransmission including the first cross-CB coded block, the retransmission further comprises a second retransmission including a second cross-CB coded block, and the second cross-CB coded block is generated by encoding, according to the LDPC code, a part of information bits of the first cross-CB coded block.

10. The method of claim 6, wherein the retransmission comprises an i^{th} retransmission and a j^{th} retransmission, wherein i>j, and a code rate of the i^{th} retransmission satisfies:
$$\frac{{K}_{j} - {K}_{i}}{{N}_{j} - {K}_{i}} < \frac{{K}_{i}}{{N}_{i}}$$
wherein:
$$\frac{{K}_{i}}{{N}_{i}}$$
represents a code rate of the i^{th} retransmission;
Kᵢ represents a number of information bits in each CB of the i^{th} retransmission;
Nᵢ represents code bits of the i^{th} retransmission;
Kⱼ represents a number of information bits in each CB of the j^{th} retransmission; and
Nⱼ represents code bits of the j^{th} retransmission.

11. An apparatus comprising:
at least one processor; and
a memory coupled to the at least one processor, the memory storing instructions that, when executed by the at least one processor, cause the apparatus to perform operations including:
transmitting an initial transmission comprising multiple code blocks (CBs); and
transmitting a retransmission comprising one or more cross-CB coded blocks, wherein the cross-CB coded blocks comprise a first cross-CB coded block, and the first cross-CB coded block is generated by encoding, according to a low density parity check (LDPC) code, a part of information bits of the multiple CBs, and wherein a code rate of the retransmission is lower than a code rate of the initial transmission.

12. The apparatus of claim 11, wherein the part of information bits of the multiple CBS comprises one or more of:
bits corresponding to variable nodes of each CB of the multiple CBs, wherein degrees of the variable nodes are less than a threshold;
bits corresponding to ending-most positions of each CB of the multiple CBs; or
bits corresponding to beginning-most positions of each CB of the multiple CBs.

13. The apparatus of claim 11, wherein the retransmission comprises a first retransmission including the first cross-CB coded block, the retransmission further comprises a second retransmission including a second cross-CB coded block, and the second cross-CB coded block is generated by encoding, according to the LDPC code, a part of information bits of the first cross-CB coded block.

14. The apparatus of claim 11, wherein the retransmission comprises an i^{th} retransmission and a j^{th} retransmission, wherein i>j, and a code rate of the i^{th} retransmission satisfies:
$$\frac{{K}_{j} - {K}_{i}}{{N}_{j} - {K}_{i}} < \frac{{K}_{i}}{{N}_{i}}$$
wherein:
$$\frac{{K}_{i}}{{N}_{i}}$$
represents a code rate of the i^{th} retransmission;
Kᵢ represents a number of information bits in each CB of the i^{th} retransmission;
Nᵢ represents code bits of the i^{th} retransmission;
Kⱼ represents a number of information bits in each CB of the j^{th} retransmission; and
Nⱼ represents code bits of the j^{th} retransmission.

15. The apparatus of claim 11, wherein the operations further include:
performing an interleaving operation in the part of information bits of the multiple CBS; and
generating the first cross-CB coded block by encoding, according to the LDPC code, the part of the information bits of the multiple CBS.

16. An apparatus comprising:
at least one processor; and
a memory coupled to the at least one processor, the memory storing instructions that, when executed by the at least one processor, cause the apparatus to perform operations including:
receiving an initial transmission comprising multiple code blocks (CBs); and
receiving a retransmission comprising one or more cross-CB coded blocks, wherein the cross-CB coded blocks comprises a first cross-CB coded block, and the first cross-CB coded block is generated by encoding, according to a low density parity check (LDPC) code, a part of information bits of the multiple CBs, and wherein a code rate of the retransmission is lower than a code rate of the initial transmission.

17. The apparatus of claim 16, wherein the operations further include:
decoding the first cross-CB coded block of the retransmission; and
after the decoding the first cross-CB coded block, decoding the multiple CBs of the initial transmission based on decoded results of the first cross-CB coded block.

18. The apparatus of claim 16, wherein the part of information bits of the multiple CBs comprises one or more of:
bits corresponding to variable nodes of each CB of the multiple CBs, wherein degrees of the variable nodes are less than a threshold;
bits corresponding to ending-most positions of each CB of the multiple CBs; or
bits corresponding to beginning-most positions of each CB of the multiple CBs.

19. The apparatus of claim 16, wherein the retransmission comprises a first retransmission including the first cross-CB coded block, the retransmission further comprises a second retransmission including a second cross-CB coded block, and the second cross-CB coded block is generated by encoding, according to the LDPC code, a part of information bits of the first cross-CB coded block.

20. The apparatus of claim 16, wherein the retransmission comprises an i^{th} retransmission and a j^{th} retransmission, wherein i>j, and a code rate of the i^{th} retransmission satisfies:
$$\frac{{K}_{j} - {K}_{i}}{{N}_{j} - {K}_{i}} < \frac{{K}_{i}}{{N}_{i}}$$
wherein:
$$\frac{{K}_{i}}{{N}_{i}}$$
represents a code rate or the i^{th} retransmission;
Kᵢ represents a number of information bits in each CB of the i^{th} retransmission;
Nᵢ represents code bits of the i^{th} retransmission;
Kⱼ represents a number of information bits in each CB of the j^{th} retransmission; and
Nⱼ represents code bits of the j^{th} retransmission.
